(19) United States
(12) Patent Application Publication
(10) Pub. No.: US 2006/0082288 A1
(43) Pub. Date: Apr. 20, 2006

(54) Light emitting devices with mixed phosphors

(76) Inventors: Hisham Menkara, Mableton, GA (US); Christopher Summers, Atlanta, GA (US); Brent K. Wagner, Marietta, GA (US)

Correspondence Address: Christopher J. Whewell;Western Patent Group, 6020 Tonkowa Trail, Georgetown, TX, 78628, US

(21) Appl. No.: 11/264,365

(22) Filed: Nov. 1, 2005

Related U.S. Application Data
(63) Continuation-in-part of application No. 10/661,931, filed on Sep. 15, 2003, now Pat. No. 6,987,353.
(63) Continuation-in-part of application No. 10/801,067, filed on Mar. 15, 2004.
(63) Continuation-in-part of application No. 10/801,082, filed on Mar. 15, 2004.
(60) Provisional application No. 60/492,008, filed on Aug. 2, 2003.

(51) Int. Cl. H01L 33/00

(52) U.S. Cl. 313/503

(57) ABSTRACT

The invention provides compositions, which are mixtures of phosphors. The compositions comprise a first component described by the formula: M1SₓSe_{y}:B1 and a second component that comprises a material described by the formula M2Aₘ(SₚSe_{q})ₙ:B2, in which: M1 and M2 may be any metal species and B1 and B2 may be any activator, typically a metal species, with the remaining variables representing effective numerical values necessary for conferring electrical neutrality to the compositions. A phosphor mixture according to the invention is produced by first preparing individual components, and then physically mixing the components, as in a mortar or ball mill.

### CROSS-REFERENCE TO RELATED APPLICATIONS

This application is a Continuation-In-Part of U.S. patent application Ser. No. 10/661,931 filed on Sep. 15, 2003; Ser. No. 10/801,067 filed Mar. 15, 2004; Ser. No. 10/801,082 filed Mar. 15, 2004, all currently still pending, and to U.S. provisional patent application Ser. No. 60/492,008 filed Aug. 2, 2003, the entire contents of all of which are herein incorporated fully by reference thereto.

### TECHNICAL FIELD

The present invention relates generally to solid-state light-emitting devices. More particularly, it relates to light emitting diodes, electroluminescent devices, and the like which comprise improved solid state materials having enhanced performance and efficiency over similar devices of the prior art.

### BACKGROUND INFORMATION

There have been few major improvements in conventional lighting (i.e. incandescent, halogen, and fluorescent lamps) over the past 20 years. However, in the case of light emitting diodes (“LEDs”), operating efficiencies have been improved to the point where they are replacing incandescent and halogen lamps in traditional monochrome lighting applications, such as traffic lights and automotive taillights. This is due in part to the fact that LEDs have many advantages over conventional light sources that include long life, ruggedness, low power consumption, and small size. LEDs are monochromatic light sources, and are currently available in various colors from UV-blue to green, yellow, and red. Furthermore, due to LEDs' narrow-band emission characteristics, a white color LED can only be produced by: 1) arranging individual red, green, and blue (R, G, B) LEDs closely together and then diffusing and mixing the light emitted by them; or 2) combining a short-wave UV or blue LED with broadband fluorescent compounds that convert part or all of the LED light into longer wavelengths.

When creating a white LED using the first approach described above, several problems arise due to the fact that the R, G, B light emitting devices are made of different semiconductor materials, which require different operating voltages and, therefore, complex driving circuitry. Another disadvantage arises from the low color-rendering characteristic of the resulting white light due to the monochromatic nature of the R, G, B LED emissions.

The second approach for producing white light from LEDs is in general more preferred, since it only requires a single type of LED (either UV or blue) coated with one or more fluorescent materials, thereby making the overall construct of a white light producing LED more compact, simpler in construction, and lower in cost versus the former alternative. Furthermore, the broadband light emission provided by most fluorescent materials or phosphors allows the possibility of high color-rendering white light.

A recent breakthrough in the efficiency of UV/blue LEDs has resulted in phosphor-coated blue LEDs becoming a serious contender for conventional incandescent bulbs used in the current illumination and display backlighting applications. Most of the current commercially available devices work by converting a portion of the blue LED emission to yellow. In such a situation, some of the blue light from the LED is transmitted through the phosphor and mixed with the yellow phosphor emission, thereby resulting in a perceived white light.

### BRIEF SUMMARY OF THE INVENTION

The present invention provides compositions useful as phosphors in light emitting devices, which are mixtures which comprise:

A) a first component phosphor comprising a material described by the formula:
M1SₓSe_{y}:B1
in which:
M1 comprises one or more elements selected from the group consisting of: Be, Mg, Ca, Sr, Ba, Zn, subject to the proviso that Zn is not solely present; and
B1 comprises one or more elements selected from the group consisting of: Eu, Ce, Cu, Ag, Al, Th, Sb, Bi, K, Na, Cl, F, Br, I, Mg, Pr, Tm, and Mn,
   wherein the total amount of B1 present is any amount between 0.0001% and about 10% in mole percent based on the total molar weight of said composition, and wherein x and y are each independently any value between about 0 and about 1, subject to the proviso that the sum of x and y is equal to any number in the range of between about 0.75 and about 1.25; and
   B) a second component phosphor that comprises a material described by the formula:
   M2Aₘ(SₚSe_{q})ₙ:B2
   in which:
M2 comprises one or more elements selected from the group consisting of: Be, Mg, Ca, Sr, Ba, Zn;
A comprises one or more elements selected from the group consisting of: Al, Ga, In, Y, La, and Gd;
B2 comprises one or more elements selected from the group consisting of: Eu, Ce, Cu, Ag, Al, Th, Cl, Br, F, I, Mg, Pr, Tm, K, Na, and Mn,
m is selected from about 2 or about 4 and n is selected from about 4 or about 7, subject to the provisos that when m is about 2, n is about 4 and when m is about 4, n is about 7,
   wherein B2 is present in any amount between 0.0001% and about 10% in mole percent based on the total molar weight of said composition, and wherein p and q are each independently any value between 0 and 1, subject to the proviso that the sum of p and q is equal to any number in the range of between about 0.75 and about 1.25.

The invention further includes light emitting devices which comprise a phosphor mixture of the invention.

### BRIEF DESCRIPTION OF THE DRAWINGS

In the annexed drawings:

FIG. 1 shows the spectrum of light emitted by a prior art YAG:Ce phosphor;

FIGS. 2A, 2B, 2C illustrate known configurations employed to couple phosphor particles to an LED;

FIG. 3 illustrates the spectrum of a novel calcium sulfoselenide phosphor excited by a blue LED;

FIG. 4 illustrates the emission spectrum of a different composition of the calcium sulfoselenide phosphor excited by a blue LED;

FIG. 5 illustrates the emission spectra of calcium sulfoselenide phosphors excited by a UV LED;

FIG. 6 illustrates the spectrum of one of the novel thio-selenide phosphor phases excited by a blue LED;

FIG. 7 illustrates the emission spectrum of a different composition of the thio-sulfoselenide phosphor excited by a blue LED;

FIG. 8 illustrates the emission spectrum of a ZnSrGa₂(SₓSe_{y})₄:Eu phosphor excited by a blue LED;

FIG. 9 illustrates the emission spectrum of a BaSrGa₄(SSe)₇:Eu phosphor excited by a blue LED;

FIG. 10 illustrates the emission spectrum of a mixture of phosphors according to the present invention comprising SrGa₂(S_{0.67}Se_{0.33})4:Eu+CaS_{0.90}Se_{0.1}:Ce; and

FIG. 11 illustrates the emission spectrum of a mixture of phosphors according to the present invention comprising CaGa₂(Se,S)₄:Eu+SrSeS:Eu.

### DETAILED DESCRIPTION

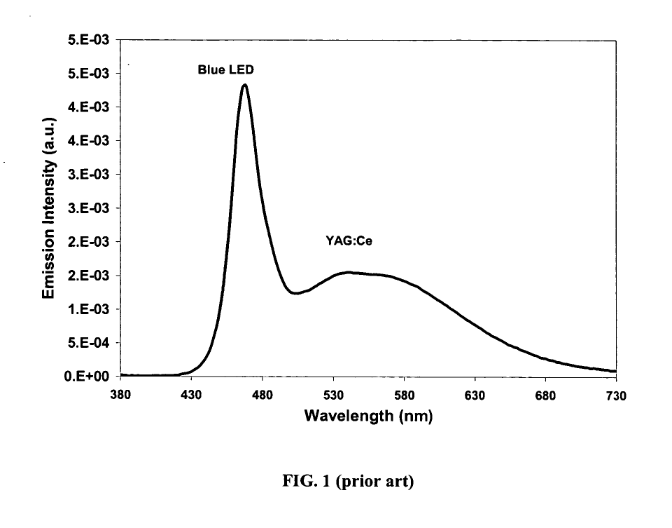

Referring to the drawings and initially to FIG. 1, there is shown an illustration of the spectrum of light emitted when conventional prior art YAG:Ce phosphors pumped by a blue LED to produce white light. In addition to the YAG:Ce, several types of organic-based fluorescent materials have also been employed, but organic molecules are susceptible to deterioration and accelerated aging when exposed to intense UV or blue light and the high temperatures present near the LED surface. However, with the exception of the YAG:Ce phosphor and its derivatives, there are very few inorganic materials that can efficiently convert blue or violet light to white while maintaining long-term stability. Furthermore, the standard YAG:Ce phosphor used in blue LEDs is deficient in both the blue green and red parts of the spectrum, resulting in low luminous efficiency and color rendering properties.

One of the advantages of using a blue LED with a single-component yellow phosphor instead of a UV LED and an RGB phosphor mix is a more stable color output over time since the latter approach suffers from differential phosphor aging due to the high temperature and light intensity near the LED surface.

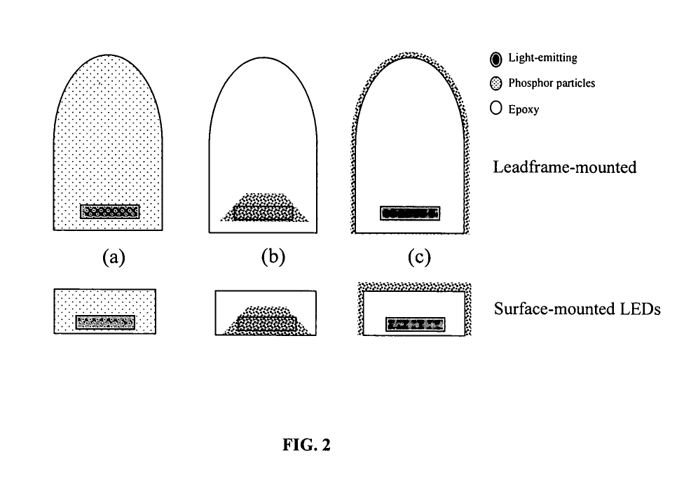

FIGS. 2A, 2B, and 2C illustrate some of the known possible configurations used to couple phosphor particles to an LED, where the phosphor can be either dispersed throughout an epoxy (FIG. 2A) as such dispersion and techniques for its production is known to those skilled in the art, or dispensed directly on the LED light emitting area (FIG. 2B), or on the outside surface of the epoxy (FIG. 2C). In these embodiments, the phosphor is disposed in sufficient proximity to said light source so as to absorb light emitted from said source, and it inherently re-emits at least a portion of the impingent light as light waves having a different wavelength from that of the light absorbed. The epoxy may encapsulate the LED. The standard commercial technique used in phosphor deposition on LED dies involves blending the phosphor powders in optically clear liquid polymer systems, such as polypropylene, polycarbonate, or polytetrafluoroethylene (PTFE), or, more commonly, epoxy resins, or silicone, as is known to those skilled in the art. The resulting material is subsequently painted or otherwise dispensed on the LED and dried, solidified, or cured. A final layer of epoxy is often subsequently applied to protect the entire assembly or to in some cases act as an optical lens for the purpose of focusing the light emitted from the LED die. The phosphors provided by the invention are well-suited to being processed and deposited onto substrates using conventional techniques known in the art for producing light emitting devices, such as light emitting devices.

In a preferred embodiment, the present invention provides phosphors, which are mixtures of individual phosphors, which mixtures comprise at least a first phosphor and a second phosphor, as now described below.

### The First Component Phosphor

A mixture of phosphors according to the present invention comprises a first component phosphor and a second component phosphor. A class of phosphors useful as the first component phosphor in such mixtures is described by the formula:
M1SₓSe_{y}:B1
in which x and y are each independently any value between about 0 and about 1, including 0 and 1, and every value therebetween; M1 is one or more of Be, Mg, Ca, Sr, Ba, Zn, excepting Zn alone; and the activator B1 comprises an element selected from the group consisting of Eu, Ce, Cu, Ag, Al, Th, Sb, Bi, K, Na, Cl, F, Br, I, Mg, Pr, Tm, and Mn, wherein this element may be present in any amount between 0.0001% and about 10% in mole percent based on the total molar weight of the composition. In one embodiment, the sum of x and y is equal to any number between about 0.5 and about 1.5. According to another embodiment, the sum of x and y is equal to any number between about 0.75 and about 1.25. According to yet another embodiment B1 is present as Eu in any amount between about 0.0001% and about 10% by weight based upon the phosphor's total weight. According to another embodiment, B1 is present as Ce in any amount between about 0.0001% and about 10% by weight based upon the phosphor's total weight. According to an another embodiment, 0.5≦x≦1 and 0≦y≦0.5 in the above formula. According to another embodiment, x is about 0 and y is about 1 in the above formula. According to another embodiment, 0≦x≦0.5 and 0≦y≦0.5 in the above formula. According to another embodiment, x is about 1 and y is about 0 in the above formula. According to another embodiment, 0≦x≦0.5 and 0.5≦y≦1.0 in the above formula. According to another embodiment, x is about 0.75 and y is about 0.25 in the above formula.

In another embodiment, the first component of a phosphor mixture of the invention comprises a phosphor as described by the formula:
M1SₓSe_{y}:B1
in which x and y are each independently any value between about 0 and about 1, including without limitation 0.001 and 1, and every thousandth therebetween, and M1 is one or more of Be, Mg, Ca, Sr, Ba, Zn, excepting Zn alone; and wherein the activator(s) B1 comprises more than one element selected from the group consisting of: Eu, Ce, Cu, Ag, Al, Tb, Sb, Bi, K, Na, Cl, F, Br, I, Mg, Pr, Tm, and Mn, including mixtures comprising any two, any three, any four, any five, any six, any seven, or more of these elements in any proportion, and wherein the elements in these mixtures may each independently be present in any amount between 0.0001% and about 10% in mole percent based on the total molar weight of said composition. In one embodiment, the sum of x and y is equal to any number between about 0.5 and about 1.5. According to another embodiment, the sum of x and y is equal to any number between about 0.75 and about 1.25. According to another embodiment, activator B1, is present as Eu in any amount between about 0.0001% and about 10% by weight based upon the phosphor's total weight. Also, one or more additional activators selected from the group consisting of Ce, Cu, Ag, Al, Tb, Sb, Bi, K, Na, Cl, F, Br, I, Mg, Pr, Tm, and Mn may be present, including mixtures of any two or more of the foregoing, in any proportion, and which additional activators are present independently of the amounts of other constituents of said composition in any amount between about 0.0001% and about 10% by weight based on the phosphor's total weight. According to another embodiment of the invention, 0.5≦x≦1 and 0≦y≦0.5 in the above formula. According to another embodiment, x is about 1 and y is about 0 in the above formula. According to another embodiment, 0≦x≦0.5 and 0≦y≦0.5 in the above formula. According to another embodiment, x is about 0 and y is about 1 in the above formula. According to another embodiment, 0≦x≦0.5 and 0.5≦y≦1.0 in the above formula. According to another embodiment, x is about 0.75 and y is about 0.25 in the above formula. According to another embodiment, activator B1 is present as Ce in any amount between about 0.0001% and about 10% by weight based upon the phosphor's total weight. Also, one or more additional activators selected from the group consisting of Eu, Cu, Ag, Al, Tb, Sb, Bi, K, Na, Cl, F, Br, I, Mg, Pr, Tm, and Mn. may be present, including mixtures of any two or more of the foregoing, in any proportion, and which additional activators are each present independently of the amounts of other constituents of said composition in any amount between about 0.0001% and about 10% by weight based on the phosphor's total weight. According to another embodiment, 0.5≦x≦1 and 0≦y≦0.5 in the above formula. According to another embodiment of the invention, x is about 1 and y is about 0 in the above formula. According to another embodiment, 0≦x≦0.5 and 0≦y≦0.5 in the above formula. According to another embodiment, x is about 0 and y is about 1 in the above formula. According to another embodiment of the invention, 0≦x≦0.5 and 0.5≦y≦1.0 in the above formula. According to another embodiment, x is about 0.75 and y is about 0.25 in the above formula.

The phosphor materials of the first component of a mixture according to the present invention are preferably synthesized using powdered metal sulfide(s) M1S and Se as the starting materials, where M1 comprises one or more of Be, Mg, Ca, Sr, Ba and Zn, excepting the case where Zn is present alone. After mixing of the raw materials in the desired molar ratio, a compound containing one or more of the desired other elements selected to be present in the final composition, which are sometimes referred to as “activating element(s)” or “activator(s)” by those skilled in the art, are slurried into the raw material mixture using distilled or de-ionized water and/or a solvent such as isopropyl alcohol, methanol, ethanol, etc. as the slurry vehicle. Dry mixing of the raw materials is also possible. Activating elements useful to provide a composition according to any embodiment of the present invention include the elements europium, cerium, copper, silver, aluminum, terbium, antimony, bismuth, potassium, sodium, chlorine, fluorine, bromine, iodine, magnesium, and manganese, and to provide such elements in a final phosphor according to the invention, it is preferable to employ compounds or salts of Eu, Ce, Cu, Ag, Al, Tb, Sb, Bi, K, Na, Cl, F, Br, I, Mg, Pr, Tm, and Mn. such as by use of halides (including Cl, Br, I, F) of metallic elements, or sulfides, oxides, or carbonates, or other raw materials which provide the activator element(s) to be present in the final composition. Additionally, it is preferable to add one or more flux materials known in the art (NH₄Cl, ZnCl₂, etc.) to enhance the reaction between the host material, which according to one preferred form of the present invention is component phosphor comprising M1SₓSe_{y}:B1 with attendant constraints and features as elsewhere set forth herein, as the use of such fluxes are known to those skilled in the art. After a thorough mechanical mixing using conventional means such as a mortar and pestle, ball mill, grinder, etc., the resulting material is fired at a temperature which is preferably in the range of about 800° C. to about 1200° C. in vacuum, inert, or reducing atmosphere, to create a M1SₓSe_{y}:B1 compound, which may be luminescent. The material resulting from such firing is subsequently cooled, and then cocomminutated before an optional second firing stage at a temperature in the range of about 800° C. to about 1200° C. in vacuum, inert atmosphere, such as in nitrogen or argon, or a reducing atmosphere such as N₂/H₂, CO, or H₂S to achieve activation. Close control of the purity of the raw materials and preparation procedures are required to obtain phase purity in these phosphors. The relative amounts of M1, S, and Se present in the final product are readily adjustable by one of ordinary skill by adjusting the relative amounts of the raw materials which contain these elements in the raw material mixture.

The manufacturing process for the first component phosphor is not limited to the one previously described, but different starting materials and synthesis techniques can be used to achieve the same results and compounds. For example, the present invention contemplates the use of both M1S and M1Se compounds as raw starting materials, which can be fired with appropriate activators in a controlled hydrogen sulfide and/or a hydrogen selenide atmosphere. The following examples are illustrative of preferred raw material mixtures, and should not be considered as delimitive of ways in which the compositions of the present invention may be prepared.

### EXAMPLE 1

CaS 100 g

Se 11 g

CeF₃ 8.2 g

The resulting composition has the formula CaS_{0.91}Se_{0.09}:Ce

### EXAMPLE 2

CaS 100 g

Se 15 g

CeF₃ 8.2 g

The resulting composition has the formula CaS_{0.88}Se_{0.12}:Ce

A first component phosphor according to the invention may be produced using mixtures of the ingredients specified in either of examples 1 or 2 above, by combining, slurry-mixing, and subsequently ball-milling in de-ionized water and/or solvent to an average particle size of about one to ten microns. After drying, the mixture is ball-milled or grinded into fine particles and then fired in a quartz crucible at 1150° centigrade for 2 hours in an inert or reducing atmosphere. The luminescent material is then removed from the crucible and sifted in a sieve shaker in order to obtain phosphors with the particle size distribution desired.

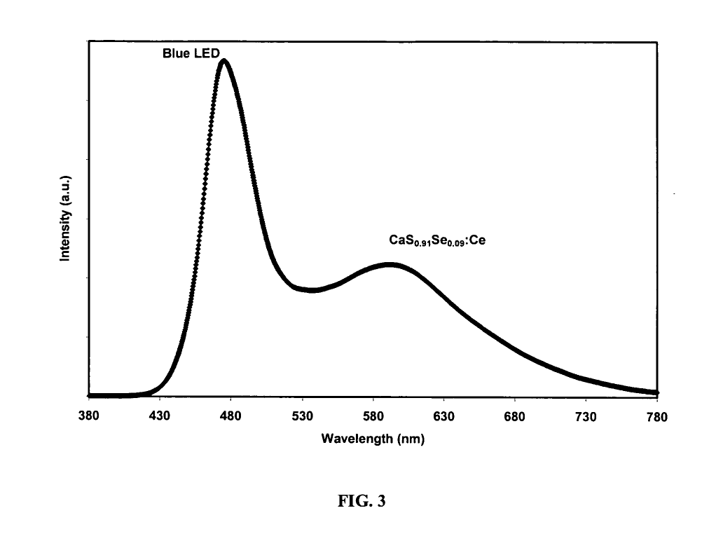

In one preferred embodiment of the invention the first component phosphor in a mixture according to the present invention provides an orange-yellow phosphor comprising the formula CaS_{0.91}Se_{0.09}:Ce in which the emission spectrum is peaked around 590 nm. The performance of this phosphor alone is shown in FIG. 3 which illustrates how one component composition of the present invention can be used to efficiently convert part of the emission from a blue LED at 475 nm to orange-yellow light around 590 nm.

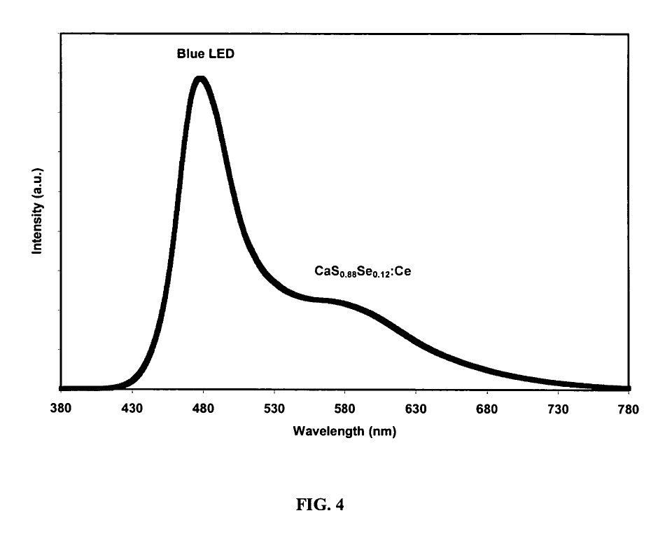

FIG. 4 illustrates the spectrum displayed by another first component phosphor composition of the present invention, CaS_{0.88}Se_{0.12}:Ce, where the peak wavelength is shifted to shorter wavelengths and efficiently converts the emission from a blue LED at 475 nm to green-yellow light around 570 nm.

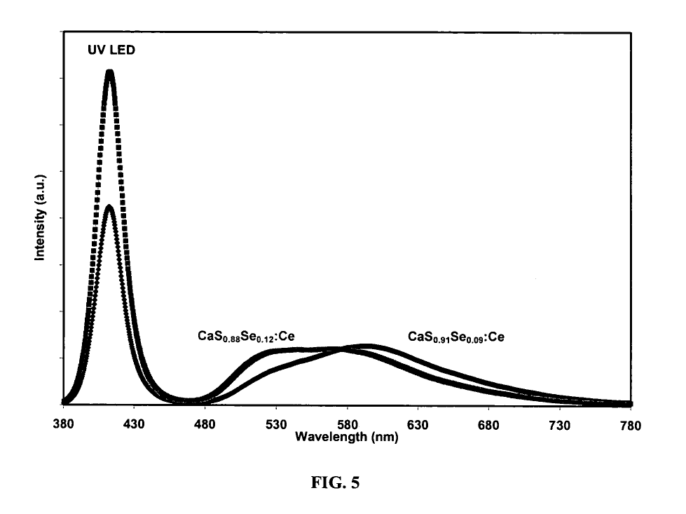

The spectra of the above two phosphors, CaS_{0.91}Se_{0.09}:Ce and CaS_{0.88}Se_{0.12}:Ce, excited by a UV LED around 410 nm are shown in FIG. 5 where the broad emission range from the phosphors are clearly illustrated. Thus, the present invention is broad with respect to the numerous possible compositions it affords one desiring of providing a first component phosphor, and the particular composition chosen by one practicing the invention will depend upon the particular requirements of the needs at hand. As can be seen in FIG. 5, increasing the Se content in the first component phosphor causes a green shift in the emission spectrum as well as a broadening of the peak. This control of the elemental components of the first component phosphor also makes it possible to shift the excitation spectrum of the phosphor from the ultraviolet to the blue region. Hence, the present invention is versatile in the number of first component phosphors possible within its scope.

### The Second Component Phosphors

The phosphor mixtures of the invention include, in addition to the first component phosphor described above under the heading of the same name, a second component phosphor, which itself comprises a phosphor which can absorb all or part of the light emitted by a light emitting diode, and which is capable of emitting light of wavelengths longer from that of the absorbed light. A second component phosphor composition provided by the invention which is useful in such regard is described by the formula:
M2A₂(SₚSe_{q})₄:B2
in which p and q are each independently any value between about 0 and about 1, including 0 and 1, including without limitation 0.001 and 1, and every thousandth therebetween; M2 is one or more of Be, Mg, Ca, Sr, Ba, Zn; and A is one or more of Al, Ga, In, Y, La, and Gd; and wherein the activator B2 comprises one or more elements selected from the group consisting of: Eu, Ce, Cu, Ag, Al, Tb, Cl, Br, F, I, Mg, Pr, Tm, K, Na, and Mn; wherein such element(s) may be present in any amount between 0.0001% and about 10% in mole percent based on the total molar weight of said composition. In one embodiment, the sum of p and q is equal to any number between about 0.500 and about 1.500. According to another embodiment, the sum of p and q is equal to any number between about 0.750 and about 1.250. According to another embodiment, B2 is present as Eu in any amount between about 0.0001% and about 10% by weight based upon the phosphor's total weight. According to another embodiment, B2 is present as Ce in any amount between about 0.0001% and about 10% by weight based upon the phosphor's total weight. According to another embodiment, 0.5≦p≦1 and 0≦q≦0.5 in the above formula. According to another embodiment, p is about 0 and q is about 1 in the above formula. According to another embodiment, 0≦p≦0.5 and 0≦q≦0.5 in the above formula. According to another embodiment, p is about 1 and q is about 0 in the above formula. According to another embodiment, 0≦p≦0.5 and 0.5≦q≦1.0 in the above formula. According to another embodiment, p is about 0.75 and q is about 0.25 in the above formula.

In another embodiment of the invention the second component phosphor is described by the formula:
M2A₂(SₚSe_{q})₄:B2
in which p and q are each independently any value between about 0 and about 1, including without limitation 0.001 and 1, and every thousandth therebetween, and M2 is one or more of Be, Mg, Ca, Sr, Ba, Zn; A is one or more of Al, Ga, In, Y, La, and Gd; and wherein the activator(s), B2 is a mixture which comprises more than one element selected from the group consisting of: Eu, Ce, Cu, Ag, Al, Tb, Cl, Br, F, I, Mg, Pr, Tm, Na, K, and Mn, including those mixtures comprising any two, any three, any four, any five, any six, any seven, or more of these elements with each present in any proportion, and wherein the elements in these mixtures may each independently be present in any amount between 0.0001% and about 10% in mole percent based on the total molar weight of said composition. In one embodiment, the sum of p and q is equal to any number between about 0.500 and about 1.500. According to another embodiment, the sum of p and q is equal to any number between about 0.750 and about 1.250. According to another embodiment, activator B2 is present as Eu in any amount between about 0.0001% and about 10% by weight based upon the phosphor's total weight. In addition, one or more additional activators selected from the group consisting of Ce, Cu, Ag, Al, Tb, Cl, Br, F, I, Mg, Pr, Tm, K, Na, and Mn may be present, including mixtures of any two or more of these elements, each present in any proportion, and which additional activators are present independently of the amounts of other constituents of said composition in any amount between about 0.0001% and about 10% by weight based on the phosphor's total weight. According to one form of the invention, 0.5≦p≦1 and 0≦q≦0.5 in the above formula. According to another embodiment, p is about 1 and q is about 0 in the above formula. According to another embodiment, 0≦p≦0.5 and 0≦q≦0.5 in the above formula. According to another embodiment, p is about 0 and q is about 1 in the above formula. According to another embodiment, 0≦p≦0.5 and 0.5≦q≦1.0 in the above formula. According to another embodiment, p is about 0.75 and q is about 0.25 in the above formula. According to another embodiment, activator B2 is present as Ce in any amount between about 0.0001% and about 10% by weight based upon the phosphor's total weight. Also, one or more additional activators selected from the group consisting of Ce, Cu, Ag, Al, Tb, Cl, Br, F, I, Mg, Pr, Tm, K, Na, and Mn may be present, including mixtures of any two or more of these elements, each present in any proportion, and which additional activators are present independently of the amounts of other constituents of said second component phosphor composition in any amount between about 0.0001% and about 10% by weight based on the phosphor's total weight. According to one alternative form of the invention, 0.5≦p≦1 and 0≦q≦0.5 in the above formula. According to another alternative form of the invention, p is about 1 and q is about 0 in the above formula. According to another alternative form of the invention, 0≦p≦0.5 and 0≦q≦0.5 in the above formula. According to another alternative form of the invention, p is about 0 and q is about 1 in the above formula. According to another alternative form of the invention, 0≦p≦0.5 and 0.5≦q≦1.0 in the above formula. According to another alternative form of the invention, p is about 0.75 and q is about 0.25 in the above formula.

Another embodiment of the present invention provides a light emitting device comprising a UV/blue light emitting diode and a mixture of phosphors comprising a first component phosphor and a second component phosphor, which absorb all or part of the light emitted by the light emitting diode, and which emit light of wavelengths longer from that of the absorbed light. A phosphor which is useful as the second component phosphor in such a mixture is described by the formula:
M2A₄(SₚSe_{q})₇:B2
in which p and q are each independently any value between about 0 and about 1, including 0 and 1, including without limitation 0.001 and 1, and every thousandth therebetween; M2 is one or more of Be, Mg, Ca, Sr, Ba, Zn; and A is one or more of Al, Ga, In, Y, La, and Gd; and wherein the activator B2 comprises one or more element(s) selected from the group consisting of: Eu, Ce, Cu, Ag, Al, Tb, Cl, Br, F, I, Mg, Pr, Tm, K, Na, and Mn; wherein this element or elements may be present in any total amount between about 0.0001% and about 10% in mole percent based on the total molar weight of the composition. In one embodiment, the sum of p and q is equal to any number between about 0.500 and about 1.500. According to another embodiment, the sum of p and q is equal to any number between about 0.750 and about 1.250. According to another embodiment B2 is present as Eu independently in any amount between about 0.0001% and about 10% by weight based upon the phosphor's total weight. According to another embodiment, B2 is present as Ce independently in any amount between about 0.0001% and about 10% by weight based upon the phosphor's total weight. According to another embodiment, 0.5≦p≦1 and 0≦q≦0.5 in the above formula. According to another embodiment, p is about 0 and q is about 1 in the above formula. According to another embodiment, 0≦p≦0.5 and 0≦q≦0.5 in the above formula. According to another embodiment, p is about 1 and q is about 0 in the above formula. According another embodiment, 0≦p≦0.5 and 0.5≦q≦0 in the above formula. According to another embodiment, p is about 0.75 and q is about 0.25 in the above formula.

In another embodiment, the second component phosphor is described by the formula
M2A₄(SₚSe_{q})₇:B2
in which p and q are each independently any value between about 0 and about 1, including without limitation 0.001 and 1, and every thousandth therebetween, and M2 is at least one of Be, Mg, Ca, Sr, Ba, Zn; A is at least one of Al, Ga, In, Y, La, and Gd; and wherein the activator(s) B2 comprises more than one element selected from the group consisting of: Eu, Ce, Cu, Ag, Al, Tb, Cl, Br, F, I, Mg, Pr, Tm, Na, K, and Mn, including mixtures comprising any two, any three, any four, any five, any six, any seven, or more of these elements independently in any proportion, and wherein the elements in these mixtures may each independently be present in any amount between about 0.0001% and about 10% in mole percent based on the total molar weight of said composition. In one embodiment, the sum of p and q is equal to any number between about 0.500 and about 1.500. According to another embodiment, the sum of p and q is equal to any number between about 0.750 and about 1.250. According to another embodiment, activator B2 is present as Eu in any amount between about 0.0001% and about 10% by weight based upon the phosphor's total weight. Also, one or more additional activators selected from the group consisting of Ce, Cu, Ag, Al, Tb, Cl, Br, F, I, Mg, Pr, Tm, Na, K, and Mn may be present, including any mixture including any two or more of the foregoing, in any proportion, and which additional activators are present independently of the amounts of other constituents of said composition in any amount between about 0.0001% and about 10% by weight based on the phosphor's total weight. According to another embodiment, 0.5≦p≦1 and 0≦q≦0.5 in the above formula. According to another embodiment, p is about 1 and q is about 0 in the above formula. According to another embodiment, 0≦p≦0.5 and 0≦q≦0.5 in the above formula. In another embodiment, p is about 0 and q is about 1 in the above formula. In another embodiment, 0≦p≦0.5 and 0.5≦q≦1.0 in the above formula. In another embodiment, p is about 0.75 and q is about 0.25 in the above formula. In another embodiment, activator B2 is present as Ce in any amount between about 0.0001% and about 10% by weight based upon the phosphor's total weight. In addition, one or more additional activators selected from the group consisting of Ce, Cu, Ag, Al, Tb, Cl, Br, F, I, Mg, Pr, Tm, Na, K, and Mn may be present, including mixtures of any two or more of the foregoing, in any proportion, and which additional activators are present independently of the amounts of other constituents of said composition in any amount between about 0.0001% and about 10% by weight based on the phosphor's total weight. In another embodiment, 0.5≦p≦1 and 0≦q≦0.5 in the above formula. In another embodiment, p=1 and q is about 0 in the above formula. In another embodiment, 0≦p≦0.5 and 0≦q≦0.5 in the above formula. In another embodiment, p is about 0 and q is about 1 in the above formula. In another embodiment, 0≦p≦0.5 and 0.5≦q≦1.0 in the above formula. In another embodiment, p is about 0.75 and q is about 0.25 in the above formula.

The phosphor materials suitable as second component phosphors according to the invention are preferably synthesized using powdered metal sulfides M2S and A₂S₃ and selenium Se as the starting materials, where M2 is at least one of Be, Mg, Ca, Sr, Ba, Zn and A is at least one of Al, Ga, In, Y, La, and Gd. After thoroughly mixing the raw materials in the desired molar ratio, a compound containing one or more of the desired other elements selected to be present in the final composition, which are sometimes referred to as “activating element(s)” or “activator(s)” by those skilled in the art, are slurried into the raw material mixture using distilled or de-ionized water and/or a solvent such as isopropyl alcohol, methanol, ethanol, etc. as the slurry vehicle. Activating elements B2 useful to provide a second component phosphor composition according to the present invention include the elements europium, cerium, copper, silver, aluminum, terbium, chlorine, iodine, magnesium, praseodymium, sodium, potassium, and manganese, and to provide such elements in a final phosphor according to the invention, it is preferable to employ compounds or salts of Eu, Ce, Cu, Ag, Al, Tb, Cl, Br, F, I, Mg, Pr, Tm, K, Na, and Mn such as by use of halides (including Cl, Br, I, F) of metallic elements, or sulfides, oxides, or carbonates, or other raw materials which provide the activator element(s) to be present in the final composition. Additionally, it is preferable to add one or more flux materials (NH₄Cl, ZnCl₂, etc.) to enhance the reaction between the host material, which according to one preferred form of the present invention is M2A₂(SₚSe_{q})₄ with attendant constraints and features as elsewhere set forth herein, as the use of such fluxes are known to those skilled in the art. After a thorough mechanical mixing using conventional means such as a mortar and pestle, ball mill, grinder, etc., the resulting material is fired at a temperature which is preferably in the range of about 7000 C to about 1200° C. in vacuum, inert, or reducing atmosphere, to create a M2A₂(SₚSe_{q})₄:B2 compound, which may be luminescent. The material resulting from such firing is subsequently cooled, and then cocomminutated before an optional second firing stage at a temperature in the range of about 700° C. to about 1200° C. in vacuum, inert atmosphere, such as in nitrogen or argon, or a reducing atmosphere such as N₂/H₂, CO, or H₂S to achieve activation. Close control of the purity of the raw materials and preparation procedures are required to obtain phase purity in these phosphors, as is known in the art. The relative amounts of M2, A, S, and Se present in the final product are readily adjustable by adjusting the relative amounts of the raw materials which contain these elements in the raw material mixture.

The production process is not limited to the one previously described, but different starting materials and synthesis techniques can be used to achieve the same results and compounds. For example, the present invention contemplates the use of a host material such as M2A₂(SₚSe_{q})₄ compound as raw starting materials, which can be fired with appropriate activators in a controlled hydrogen sulfide and/or a hydrogen selenide atmosphere. The following examples are illustrative of preferred raw material mixtures, and should not be considered as delimitive of methods by which the compositions of the present invention may be prepared.

### EXAMPLE 3

SrS 7.62 g

Ga₂S₃ 15 g

Se 10 g

Eu₂O₃ 0.56 g

The resulting composition has the formula SrGa₂(S_{0.67}Se_{0.33})₄:Eu(5%)

### EXAMPLE 4

SrS 7.62 g

Ga₂S₃ 15 g

Se 13.5 g

Eu₂O₃ 0.56 g

The resulting composition has the formula SrGa₂(S_{0.60}Se_{0.40})₄:Eu(5%).

A second component phosphor according to the invention may be produced using mixtures of the ingredients specified in either of examples 3 or 4 above, by combining, slurry-mixing, and subsequently ball-milling in de-ionized water and/or solvent to an average particle size of about one to ten microns. After drying, the mixture is ball-milled or ground into fine particles and then fired in a quartz crucible at 850° centigrade for 2 hours in an inert or reducing atmosphere. The luminescent material is then removed from the crucible and sifted in a sieve shaker in order to obtain phosphors with the particle size distribution desired.

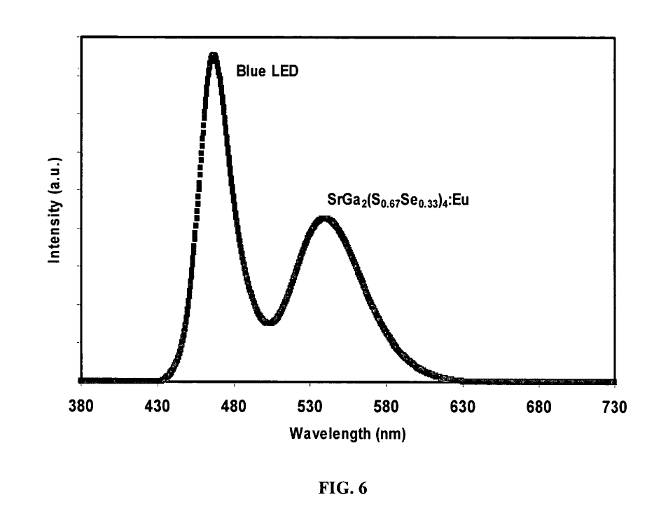

In one embodiment the present invention provides as a second component phosphor a green-yellow phosphor comprising the formula SrGa₂(SₚSe_{q})₄:Eu in which p is about 0.67; and q is about 0.33. The performance of this phosphor is shown in FIG. 6, which illustrates how one component of a composition of the present invention can be used to efficiently convert part of the emission from a blue LED at 470 nm to yellow-green light around 540 nm.

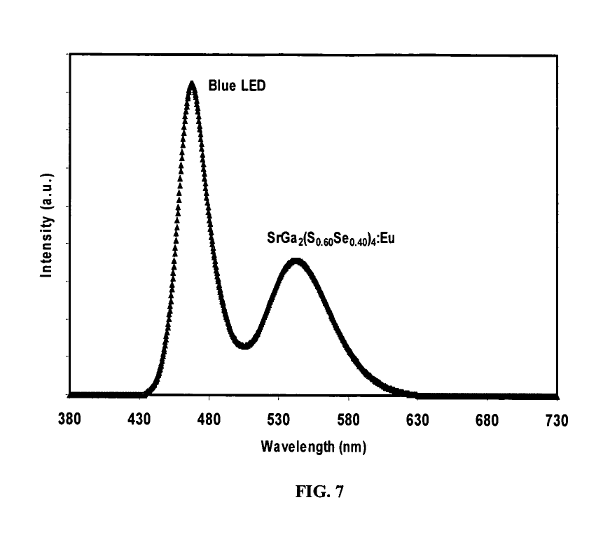

FIG. 7 is the spectrum of another second component phosphor composition of the present invention, where the peak wavelength is shifter to longer wavelengths and the emission spectrum is broadened. SrGa₂(SₚSe_{q})₄:Eu in which p is about 0.60; and q is about 0.40 that efficiently converts the emission from a blue LED at 470 nm to green-yellow light around 541 nm.

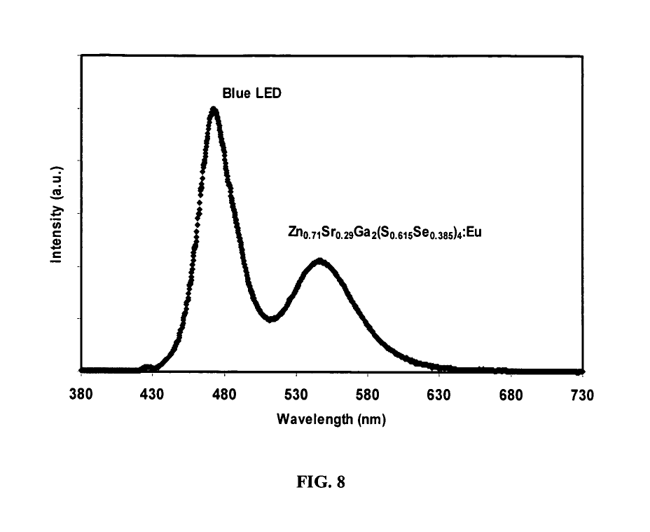

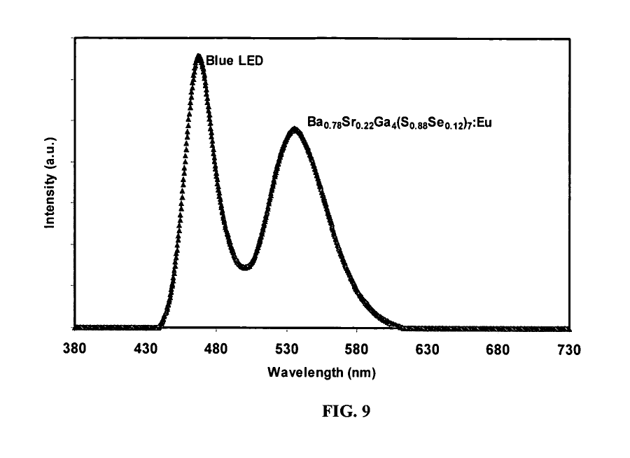

In another embodiment, there is provided by the present invention a second component phosphor based on ZnᵤSrᵥGa₂(SₚSe_{q})₄:Eu in which p is about 0.615; q is about 0.385 and u=0.71; v=0.29, based upon starting materials quantities, which has an emission peak around 548 nm and a broadened spectrum, with approximately an 11 nm larger full width at half of the maximum absorption (“FWHM”), compared to those shown in FIG. 6 and FIG. 7. The spectrum of this phosphor excited by a blue LED is shown in FIG. 8. In another embodiment the present invention provides a second component phosphor which comprises a luminescent phosphor based on BaᵤSrᵥGa₄(SₚSe_{q})₇:Eu in which p is about 0.88; q is about 0.12 and u=0.78; v=0.22. The spectrum of this phosphor excited by a blue LED is shown in FIG. 9. These phosphors are exemplary of the present invention, and shall not be construed as being delimitive of the scope of the present invention.

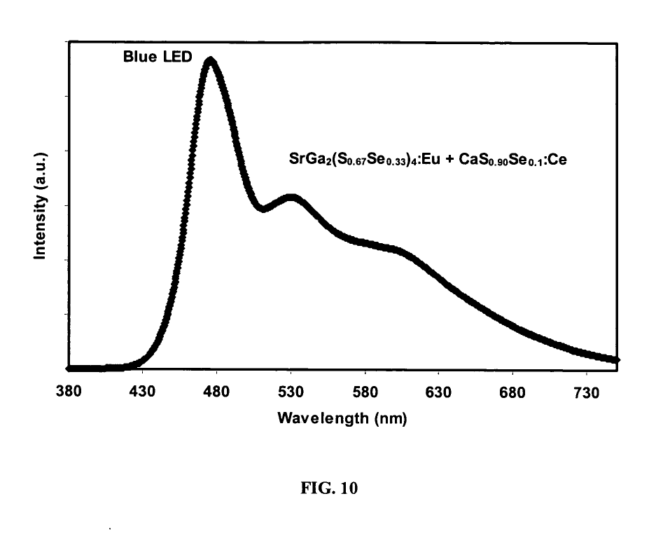

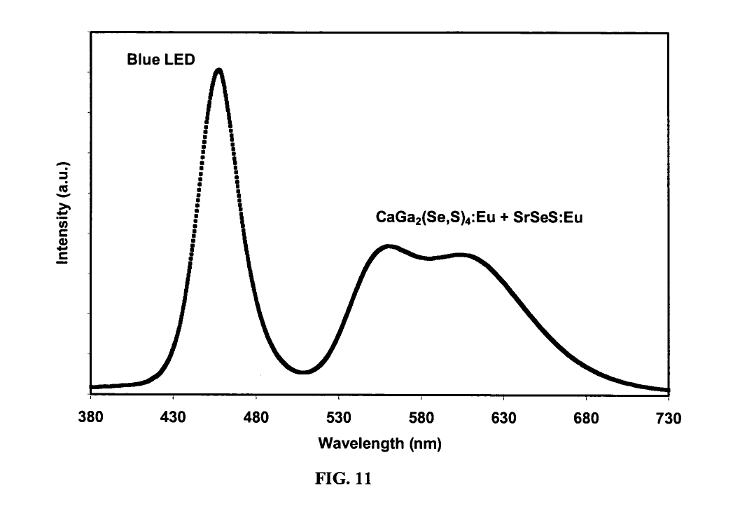

FIG. 10 is the emission spectrum of a mixture of phosphors according to the invention comprising SrGa₂(S_{0.67}Se_{0.33})4:Eu+CaS_{0.90}Se_{0.1}:Ce. FIG. 11 shows the emission spectrum of a mixture of phosphors according to the present invention comprising CaGa₂(Se,S)₄:Eu+SrSeS:Eu. These are but two of the many mixtures provided by the present invention.

Thus, one of ordinary skill in the art immediately recognizes that the present invention is broad with respect to the numerous possible compositions of second component phosphors possible for use in a mixture according hereto, and the particular composition for the second component phosphor chosen by one practicing the invention will depend upon the particular requirements of the needs at hand. As can be seen in FIG. 8, adjusting the Se content as well as the composition of M2 creates a red shift in the emission spectrum as well as a broadening of the spectrum. This control of the components of the phosphor also makes it possible to shift the excitation spectrum of the phosphor from the ultraviolet to the blue region. Hence, the present invention is versatile in the number of phosphors possible within its scope. A phosphor mixture according to the invention may be produced by first preparing individual components, as herein described, and subsequently physically mixing the components, as in a mortar or ball mill.

The present invention includes mixtures containing all proportions of the first component phosphor in combination with the second component phosphor. For example, first component phosphor A may be present in any amount between about 99.9% and 0.1% by weight based on the total weight of the mixture of phosphors. Additionally, second component phosphor B may be present in any amount between about 0.1% and 99.9% by weight based on the total weight of the mixture of phosphors. In one embodiment, component A is present in the range of between about 10-30% by weight based on the total weight of the mixture, and component B is present in any amount in the range of between about 90-70% by weight based on the total weight of the mixture. In another embodiment, component B is present in the range of between about 10-30% by weight based on the total weight of the mixture, and component A is present in any amount in the range of between about 90-70% by weight based on the total weight of the mixture.

In one embodiment, component A is present in the range of between about 1-10% by weight based on the total weight of the mixture, and component B is present in any amount in the range of between about 99-90% by weight based on the total weight of the mixture. In another embodiment, component B is present in the range of between about 1-10% by weight based on the total weight of the mixture, and component A is present in any amount in the range of between about 99-90% by weight based on the total weight of the mixture.

In one embodiment, component A is present in the range of between about 30-50% by weight based on the total weight of the mixture, and component B is present in any amount in the range of between about 70-50% by weight based on the total weight of the mixture. In another embodiment, component B is present in the range of between about 30-50% by weight based on the total weight of the mixture, and component A is present in any amount in the range of between about 70-50% by weight based on the total weight of the mixture. In another embodiment, the relative amounts of first component phosphor and second component phosphor are about equal on a weight basis. Thus, the present invention includes mixtures of the phosphors described herein in all proportions with one another, and which mixtures may further include other prior art phosphors, such as YAG, in any amount or proportion defined herein as being a suitable amount of the first component phosphor in such a mixture.

Throughout this specification and the claims appended hereto, ranges are provided in relation to certain variables used to describe relative amounts of elemental constituents present in a composition of the invention in the format of: 0≦x≦1. Such format is written with the intent that the reader of this specification and the claims appended hereto shall interpret such a range as including all numerical values between zero and one. As examples, given for the sole purpose of clarity and avoidance of doubt as to the breadth and scope of the meaning of this range within this specification and its claims, the range 0≦x≦1 includes, without limitation, the numerical values represented by 0.000001, 0.067, ½, ⅙, 0.3333, 0.75, ⅔, 0.41666666, 0.9999999, 0.99, 100/101, π/4, 0.74, 0.73999, 0.7400009, 0.1, 0.2, 0.3, 0.4, 0.5, 0.6, 0.7, 0.8, 0.9, 1, 0.50001, as well as all ranges encompassed by the selection of any two numerical values, each of which individually have a value between 0 and 1. In general, a given numerical value qualifies as being in the range of between 0≦x≦1 if the numerical value under consideration yields a number having an absolute value of any number in the range of between 2≦x≦3 when the numerical value under consideration is subtracted from 3. Thus, the expression 0≦x≦1 inherently includes such ranges as 0≦x≦0.1 and 0.001≦x≦0.79004217. In cases of ranges which might come to mind such as 0.001≦x≦0.79004217 where the number of significant figures present at one end of the ranges is less than the number of significant figures at the other end of the range, the reader is hereby instructed to add an appropriate number of zeros as placeholders to compensate for any discrepancy perceived as blocking their interpretation of mathematical values.

The phrase: “present in any amount between about 0.0001% and about 10% in mole percent based on the total molar weight of said composition” frequently occurs in the present specification and the claims appended hereto. Substitution of this foregoing phrase with “present in any amount between about 0.0001% and about 10% in weight percent based upon the total weight of said composition (or phosphor, as the case may be)” in every occurrence provides further alternative embodiments of the invention.

Consideration must be given to the fact that although this invention has been described and disclosed in relation to certain preferred embodiments, obvious equivalent modifications and alterations thereof will become apparent to one of ordinary skill in this art after reading and understanding this specification and the claims appended hereto. This includes the subject matter defined by any combination of any one of the various claims appended hereto with any one or more of the remaining claims, including the incorporation of the features of any dependent claim, singly or in combination with other dependent claims into any independent claim, either alone or in combination with the features or limitations of any other independent claim, with the remaining dependent claims in their original text being read and applied to and independent claim so modified. Further, it is to be understood that the use of the word “about” as a modifier for a numerical value includes the actual numerical value itself. for example, where the phrase “wherein x is about 1” or phrases of similar import are provided, such language includes the situation wherein x equals 1. The presently-disclosed invention accordingly covers all such modifications, alterations, and permutations.

What is claimed is:

1) A light emitting device comprising:
a) a light source selected from the group consisting of: light-emitting diodes, electroluminescent devices, and lasers, wherein said light source emits light having a wavelength of between about 360 and about 480 nanometers; and
b) a phosphor mixture comprising:
A) a first component phosphor comprising a material described by the formula:
M1SₓSe_{y}:B1
in which:
M1 comprises one or more elements selected from the group consisting of: Be, Mg, Ca, Sr, Ba, Zn, subject to the proviso that Zn is not solely present;
B1 comprises one or more elements selected from the group consisting of: Eu, Ce, Cu, Ag, Al, Tb, Sb, Bi, K, Na, Cl, F, Br, I, Mg, Pr, Tm, and Mn;
wherein the total amount of B1 present is any amount between 0.0001% and about 10% in mole percent based on the total molar weight of said composition, and wherein x and y are each independently any value between about 0 and about 1, subject to the proviso that the sum of x and y is equal to any number in the range of between about 0.75 and about 1.25; and
B) a second component phosphor that comprises a material described by the formula:
M2Aₘ(SₚSe_{q})ₙ:B2
in which:
M2 comprises one or more elements selected from the group consisting of: Be, Mg, Ca, Sr, Ba, Zn;
A comprises one or more elements selected from the group consisting of: Al, Ga, In, Y, La, and Gd;
B2 comprises one or more elements selected from the group consisting of: Eu, Ce, Cu, Ag, Al, Tb, Cl, Br, F, I, Mg, Pr, Tm, K, Na, and Mn,
m is selected from about 2 or about 4 and n is selected from about 4 or about 7, subject to
the provisos that when m is about 2, n is about 4 and when m is about 4, n is about 7, wherein B2 is present in any amount between 0.0001% and about 10% in mole percent based on the total molar weight of said composition, and wherein p and q are each independently any value between 0 and 1, subject to the proviso that the sum of p and q is equal to any number in the range of between about 0.75 and about 1.25, and wherein said phosphor mixture is disposed in sufficient proximity to said light source so as to absorb light emitted from said source.

2) A composition according to claim 1 wherein 0≦x≦1 and 0≦y≦1.

3) A composition according to claim 1 wherein 0.5≦x≦1 and 0≦y≦0.5.

4) A composition according to claim 1 wherein 0≦x≦0.5 and 0≦y≦0.5.

5) A composition according to claim 1 wherein 0≦x≦0.5 and 0.5≦y≦1.

6) A composition according to claim 1 wherein x is about 0 and y is about 1.

7) A composition according to claim 1 wherein x is about 1 and y is greater than 0.

8) A composition according to claim 1 wherein M1 comprises one or more elements selected from the group consisting of: calcium and magnesium.

9) A composition according to claim 8 wherein said activator B1 comprises one or more elements selected from the group consisting of cerium and europium.

10) A composition according to claim 1 wherein B1 comprises a single element selected from the group consisting of: Eu, Ce, Cu, Ag, Al, Tb, Sb, Bi, K, Na, Cl, F, Br, I, Mg, Pr, Tm, and Mn.

11) A composition according to claim 1 wherein B1 comprises two or more elements selected from the group consisting of: Eu, Ce, Cu, Ag, Al, Th, Sb, Bi, K, Na, Cl, F, Br, I, Mg, Pr, Tm, and Mn.

12) A composition according to claim 1 wherein M1 comprises a single element selected from the group consisting of: Be, Mg, Ca, Sr, and Ba.

13) A composition according to claim 1 wherein M1 comprises two or more elements selected from the group consisting of: Be, Mg, Ca, Sr, Ba, and Zn.

14) A composition according to claim 1 wherein 0≦p≦1 and 0≦q≦1.

15) A composition according to claim 1 wherein 0.5≦p≦1 and 0≦q≦0.5.

16) A composition according to claim 1 wherein 0≦p≦0.5 and 0≦q≦0.5.

17) A composition according to claim 1 wherein 0≦p≦0.5 and 0.5≦q≦1.0.

18) A composition according to claim 1 wherein p is about 0, and q is about 1.

19) A composition according to claim 1 wherein p is about 1, and q is greater than 0.

20) A composition according to claim 1 wherein M2 comprises zinc and strontium.
